(19) United States
(12) Patent Application Publication
(10) Pub. No.: US 2024/0275300 A1
(43) Pub. Date: Aug. 15, 2024

(54) MODULE FOR SUPPLYING ELECTRICAL ENERGY

(71) Applicant: Schneider Electric Industries SAS, Rueil Malmaison (FR)

(72) Inventor: Stéphane Sicard, La Mure (FR)

(73) Assignee: Schneider Electric Industries SAS, Rueil Malmaison (FR)

(21) Appl. No.: 18/430,710

(22) Filed: Feb. 2, 2024

(30) Foreign Application Priority Data
Feb. 13, 2023 (FR) 2301312

(51) Int. Cl. H02M 7/25; G01R 27/26; H02M 1/00

(52) U.S. Cl. CPC H02M 7/25; G01R 27/2605; H02M 1/0048

(57) ABSTRACT

A module for supplying electrical energy configured to convert alternating electrical energy into direct electrical energy to power a resistive load. The module includes a current transformation block including a magnetic current transformer having an equivalent magnetizing inductance, a block for converting alternating voltage into direct voltage, an energy storage block, and an output voltage regulation block suitable for supplying electrical energy to the resistive load. The block for converting alternating voltage into direct voltage includes a compensation capacitor configured to compensate an energy loss due to the magnetic current transformer, the block for converting alternating voltage into direct voltage being connected between the current transformation block and the energy storage block.

### TECHNICAL FIELD

The present invention relates to a module for supplying electrical energy, configured to convert alternating electrical energy into direct electrical energy to power a resistive load.

The invention lies in the field of supplying electrical power to loads.

More particularly, the invention lies in the field of supplying electrical energy by recovering electrical energy from a magnetic field formed around a conductor passed through by an electrical current.

### BACKGROUND

The use of a current transformer and of a current rectifier, configured to obtain direct electrical energy from alternating electrical energy (or AC/DC), is known but such conventional current transformers have a bulk that is not compatible with some applications.

### SUMMARY

An objective of the invention is to propose a module for supplying electrical energy, intended to supply electrical current/voltage to an electronic device (e.g. a circuit board) integrated in a device for measuring electrical quantities. This measurement device is thus autonomous in terms of electrical power supply.

In this context, there is a need to provide a module for supplying electrical energy capable of supplying a minimum electrical current of a few hundreds of microamperes (μA), upon start-up, while complying with dimension constraints.

To this end, the invention proposes, according to one aspect, a module for supplying electrical energy configured to convert alternating electrical energy into direct electrical energy to power a resistive load, comprising a current transformation block comprising a magnetic current transformer having an equivalent magnetizing inductance, a block for converting alternating voltage into direct voltage, an energy storage block, and an output voltage regulation block suitable for supplying electrical energy to the resistive load. The block for converting alternating voltage into direct voltage comprises a compensation capacitor configured to compensate an energy loss due to the magnetic current transformer, the block for converting alternating voltage into direct voltage being connected between the current transformation block and the energy storage block.

Advantageously, the proposed module for supplying electrical energy is compact, thanks to the compensation capacitor configured to compensate an energy loss due to the equivalent magnetizing inductance of the magnetic current transformer. Specifically, the compensation capacitor creates a resonant effect with the current transformation block, which makes it possible to optimize energy collection, and consequently, to reduce the size of the components of the current transformation block to use for the same electrical energy supplied.

The module for supplying electrical energy according to the invention may have one or more of the features below, taken independently or in any admissible combination.

The block for converting alternating voltage into direct voltage is a voltage multiplier block comprising said compensation capacitor, a first non-return diode connected to the output of the compensation capacitor, configured to prevent electrical current returning to said compensation capacitor, and a second non-return diode, connected between a connection point situated between the compensation capacitor and the first non-return diode, and an earth point, the second non-return diode being configured to prevent current passing between said connection point and earth.

The block for converting alternating voltage into direct voltage further comprises a capacitor, connected between the earth point and the output of the first non-return diode.

The compensation capacitor has a capacitance chosen as a function of an equivalent magnetizing inductance of the magnetic current transformer.

The capacitance of the compensation capacitor is calculated using the following formula:

$${C}_{1} = \frac{1}{{L}_{1} \times {ω}_{0}^{2}}$$

in which C1 is the capacitance of the compensation capacitor, L1 is the equivalent magnetizing inductance of the magnetic current transformer and ω₀ is the pulsation of the alternating electrical current at the output of the current transformation block.

The energy storage block comprises a storage capacitor, connected between an output point of the conversion block and an earth point.

The module further comprises an impedance matching block, connected between the block for converting alternating voltage into direct voltage and the energy storage block, the impedance matching block carrying out equalization between a load impedance and a source impedance, said energy storage block comprising a storage capacitor, connected between an output point of the impedance matching block and an earth point.

The impedance matching block comprises an inductive component, connected to the output of the voltage conversion block, a diode connected to the output of the inductive component and a transistor, connected between a connection point situated between the output of said inductive component and the input of said diode, the transistor being controlled by a control signal dependent on a voltage comparison between a setpoint voltage and an output voltage of the module for supplying electrical energy.

The voltage conversion block, the impedance matching block, the energy storage block and the voltage regulation block are implemented by an electronic processing unit.

### BRIEF DESCRIPTION OF THE DRAWINGS

Other features and advantages of the invention will emerge from the description which is given thereof below by way of indicative and non-limiting example, with reference to the appended figures, among which:

FIG. 1 is a representation of the main blocks of a module for supplying electrical energy according to one embodiment;

FIG. 2 is an exemplary implementation of the blocks of a module for supplying electrical energy according to a first embodiment;

FIG. 3 is an equivalent electrical model of the magnetic current transformer from FIG. 2;

FIG. 4 is a graph of curves illustrating electrical energy supply performances.

### DETAILED DESCRIPTION

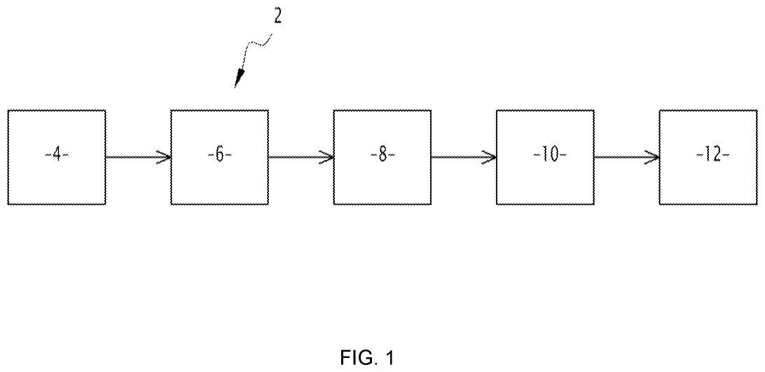

FIG. 1 illustrates the main blocks of a module for supplying electrical energy 2.

The module 2 for supplying electrical energy is configured to collect electrical energy from the magnetic field created by an electrical conductor.

More generally, the module 2 is configured to supply electrical energy from an alternating electrical energy source to transform it into direct electrical energy, and power a resistive load 14, e.g. a circuit board configured to perform calculations, for example to calculate characteristic values of electrical quantities in an electrical installation. In particular, a direct voltage is supplied at the output of the module 2 for supplying electrical energy to power the load.

The module 2 for supplying electrical energy comprises a current transformation block 4 comprising a current transformer.

In a known manner, a magnetic current transformer comprises primary and secondary windings (or electrical coils), the electrical currents passing through these windings being called primary current and secondary current, respectively. The secondary current is practically proportional to the primary current and out of phase with the latter by an angle close to zero for an appropriate direction of the connections.

Such a magnetic current transformer is shown by an equivalent electrical model comprising a current source and an inductive component, called equivalent magnetizing inductive component, connected in parallel with the current source. The inductance of the inductive component is hereinafter called equivalent magnetizing inductance of the magnetic current transformer.

Connected to the output of the current transformation block 4 is a block 6 for converting alternating electrical energy into direct electrical energy (AC/DC conversion), in particular configured to transform alternating voltage into direct voltage.

Hereinafter, the block 6 will be called the voltage conversion block or AC/DC conversion block.

Advantageously, this voltage conversion block 6 in particular comprises a capacitive circuit which is configured to compensate the energy losses of the equivalent magnetizing inductive component of the current transformation block 4.

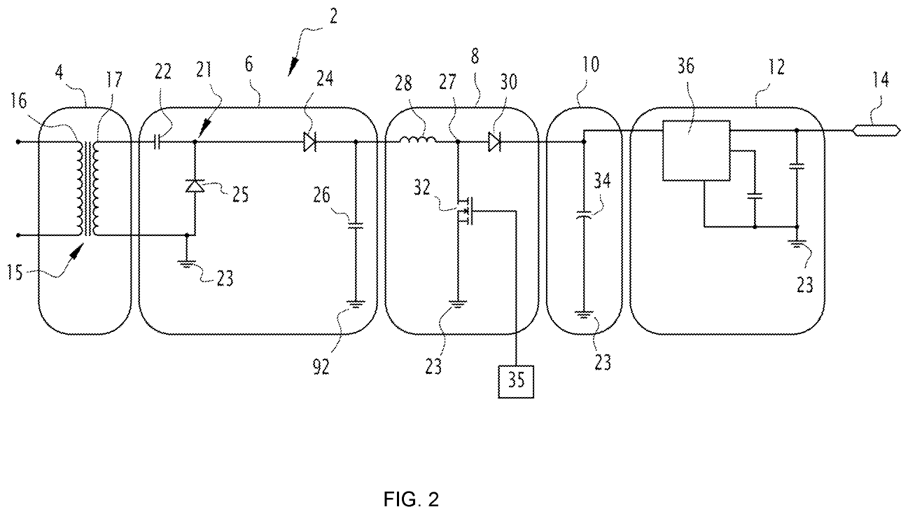

In one embodiment, the voltage conversion block 6 is a voltage multiplier, preferably a voltage doubler of the Greinacher circuit type, and more generally a voltage multiplier, as explained in more detail hereinbelow with reference to FIG. 2.

The module 2 further comprises, at the output of the voltage conversion block 6, an impedance matching block 8, the output of which is connected to the input of an electrical energy storage block 10.

The impedance matching block 8 carries out equalization between a load impedance and a source impedance.

The impedance matching block 8 is optional; embodiments without such an impedance matching block 8 are conceivable.

The module 2 for supplying electrical energy further comprises a voltage regulation block 12, suitable for regulating the direct voltage at the output of the module 2 in line with the power consumption needs of the load 14.

One embodiment of electrical circuits making it possible to implement each of the blocks functionally described hereinabove is illustrated in FIG. 2.

In this embodiment, the current transformation block 4 comprises a magnetic current transformer 15 comprising a primary winding 16 and a secondary winding 17.

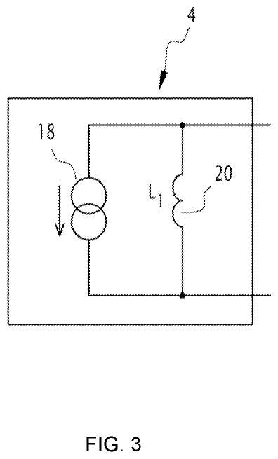

FIG. 3 illustrates an equivalent electrical model of the magnetic current transformer 4, in the form of a current source 18 and an equivalent magnetizing inductive component 20, of equivalent magnetizing inductance denoted L1.

In the embodiment from FIG. 2, the AC/DC conversion block 6 is a Greinacher voltage doubler circuit.

This AC/DC conversion block 6 comprises a capacitive circuit, in this embodiment a so-called compensation capacitor 22, having a capacitance value C1, and a first non-return diode 24 connected to the output of the compensation capacitor 22.

The first non-return diode 24 is configured to prevent electrical current returning to the compensation capacitor 22.

In addition, the AC/DC conversion block 6 comprises a second non-return diode 25, connected between a connection point 21 and a point 23 of low potential, for example connected to earth. The connection point 21 forms a connection node, between the output of the capacitor 22 and the input of the first non-return diode 24, and the output of the second non-return diode 25.

The second non-return diode 25 is configured to prevent current passing between the connection point 21 and earth 23.

Preferably, the compensation capacitor 22 has a capacitance chosen as a function of the inductance L1, equal to the equivalent magnetizing inductance of the magnetic transformer of the current transformation block 4, so as to obtain a resonance and compensate an energy loss due to the current transformer.

In one embodiment, the capacitance C1 is calculated as a function of the inductance L1 using the following formula:

$${C}_{1} = \frac{1}{{L}_{1} \times {ω}_{0}^{2}} \qquad [ MATH 1 ]$$

Where ω₀ is the pulsation of the alternating electrical current at the output of the current transformation block, where ω₀=2πf₀, f₀ being the frequency of the signal.

In addition, the AC/DC conversion block 6 further comprises another capacitor 26, connected between earth 23 and the output of the non-return diode 24. The capacitor 26 allows reserve energy to be stored, for the Greinacher circuit but also for the load.

For example, in one embodiment, the capacitor 26 has a capacitance of 10 μF.

The impedance matching block 8 is a converter of “boost DC-DC” type in this embodiment. This impedance matching block 8 comprises an inductive component 28 connected to the output of the voltage conversion block 6, a diode 30 connected to the output of the inductive component 28 and a transistor 32, connected between a connection point 27 situated between the output of the inductor 28 and the input of the diode 30, controlled by a control signal 35 dependent on the voltage supplied at the output of the module 2. The transistor 32 has a switch function, the control signal being dependent on a voltage comparison between a setpoint voltage and an output voltage of the module 2 for supplying electrical energy.

As a variant, the impedance matching block is implemented by other types of converter, for example a “buck-boost DC-DC” converter, or a converter of “buck DC-DC” type.

The transistor 32 is for example a MOSFET transistor.

The energy storage block 10 comprises a storage capacitor 34 connected between the output of the impedance matching block 8 and earth 23.

For example, the storage capacitor 34 has a capacitance of 330 μF.

The voltage regulation block 12 comprises a linear voltage regulator or a switching regulator.

Advantageously, the use of a voltage conversion block comprising a compensation capacitor makes it possible to compensate the losses induced by the magnetizing inductive component of the current transformation block.

Advantageously, the further addition of an impedance matching block makes it possible to optimize the supply of electrical energy by the module 2 for supplying electrical energy 2, while making it possible to reduce the bulk of this module 2.

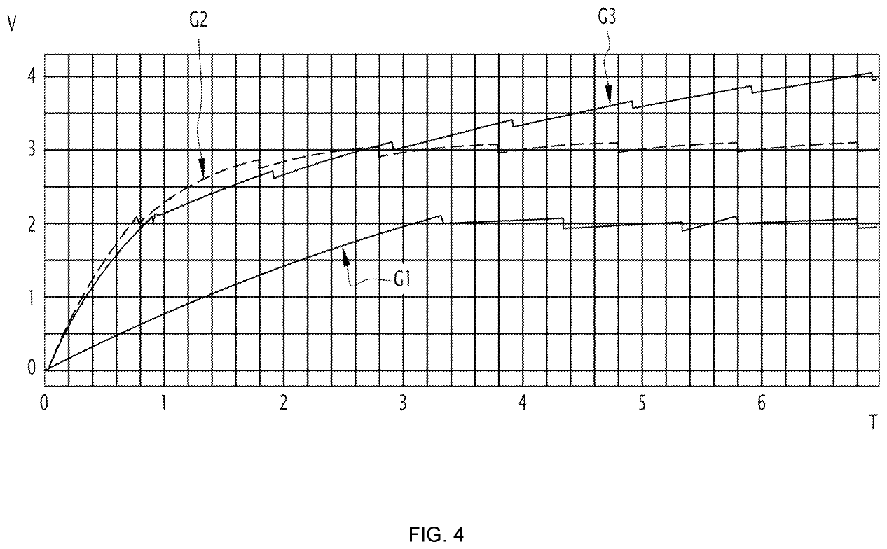

FIG. 4 illustrates the obtained performance, and more specifically the voltage supplied at the output of a module 2 for supplying electrical energy compared with a module for supplying electrical energy which is devoid of a block for converting alternating voltage into direct voltage, comprising a capacitive circuit comprising an inductance compensation capacitor, or of an impedance matching block, respectively.

FIG. 4 shows a graph, the abscissa axis showing time and the ordinate axis showing the voltage across the terminals of the storage capacitor 34.

The curve G1 shows the voltage obtained without implementing the resonance of the voltage conversion block 6 including the inductance compensation capacitor 22, and without an impedance matching block 8. A direct voltage of around 2V is obtained after the charging time of the storage capacitor 34.

The curve G2 shows the voltage obtained when the value of the compensation capacitor of the module 2 is matched with the value of the equivalent magnetizing inductance of the magnetic current transformer, (or in other words, with resonance), without an impedance matching block; the curve G3 shows the voltage obtained when the module 2 for supplying electrical energy comprises a voltage conversion block 6 with an equivalent magnetizing inductance compensation capacitor (in other words, with resonance) and with an impedance matching block 8.

As illustrated in FIG. 4, with an identical current transformation block 4, the voltage supplied by the module 2 for supplying electrical energy is much higher when the voltage conversion block 6 with resonance, then the impedance matching block 8 are used.

In the description hereinabove, the block for converting alternating voltage into direct voltage is implemented by a Greinacher voltage multiplier.

As a variant, other types of AC/DC converter comprising an inductance compensation capacitor may be implemented. Advantageously, the described module for supplying electrical energy may be integrated in a device for measuring electrical quantities, of closed type or of opening type.

For example, the current transformation block 4 is implemented in the form of a sensor comprising a through-slot suitable for receiving an electrical conductor, of closed type or of opening type, and the voltage conversion block 6, the impedance matching block 8, the energy storage block 10 and the voltage regulation block 12 are implemented by an electronic processing unit, for example in the form of integrated circuits on a circuit board.

1. A module for supplying electrical energy configured to convert alternating electrical energy into direct electrical energy to power a resistive load, comprising a current transformation block comprising a magnetic current transformer having an equivalent magnetizing inductance, a block for converting alternating voltage into direct voltage, an energy storage block, and an output voltage regulation block suitable for supplying electrical energy to the resistive load, wherein the block for converting alternating voltage into direct voltage comprises a compensation capacitor configured to compensate an energy loss due to the magnetic current transformer, the block (6) for converting alternating voltage into direct voltage being connected between the current transformation block and the energy storage block.

2. The module according to claim 1, wherein the block for converting alternating voltage into direct voltage is a voltage multiplier block comprising said compensation capacitor, a first non-return diode connected to the output of the compensation capacitor, configured to prevent electrical current returning to said compensation capacitor, and a second non-return diode, connected between a connection point situated between the compensation capacitor and the first non-return diode, and an earth point, the second non-return diode being configured to prevent current passing between said connection point and earth.

3. The module according to claim 2, wherein said block for converting alternating voltage into direct voltage further comprises a capacitor, connected between the earth point and the output of the first non-return diode.

4. The module according to claim 1, wherein the compensation capacitor has a capacitance chosen as a function of an equivalent magnetizing inductance of the magnetic current transformer.

5. The module according to claim 4, wherein the capacitance of the compensation capacitor is calculated using the following formula:
$${C}_{1} = \frac{1}{{L}_{1} \times {ω}_{0}^{2}}$$
in which C1 is the capacitance of the compensation capacitor, L1 is the equivalent magnetizing inductance of the magnetic current transformer and ω₀ is the pulsation of the alternating electrical current at the output of the current transformation block.

6. The module according to claim 1, wherein said energy storage block comprises a storage capacitor, connected between an output point of the conversion block and an earth point.

7. The module according to claim 1, further comprising an impedance matching block, connected between the block for converting alternating voltage into direct voltage and the energy storage block, the impedance matching block carrying out equalization between a load impedance and a source impedance, said energy storage block comprising a storage capacitor, connected between an output point of the impedance matching block and an earth point.

8. The module according to claim 7, wherein said impedance matching block comprises an inductive component, connected to the output of the voltage conversion block, a diode connected to the output of the inductive component and a transistor, connected between a connection point situated between the output of said inductive component and the input of said diode, the transistor being controlled by a control signal dependent on a voltage comparison between a setpoint voltage and an output voltage of the module for supplying electrical energy.

9. The module according to claim 7, wherein the voltage conversion block, the impedance matching block, the energy storage block and the voltage regulation block are implemented by an electronic processing unit.
